(19) United States
(12) Patent Application Publication
(10) Pub. No.: US 2025/0101567 A1
(43) Pub. Date: Mar. 27, 2025

(54) DEPOSITION MASK AND METHOD OF FABRICATING THE SAME

(71) Applicant: Samsung Display Co., LTD., Yongin-si (KR)

(72) Inventors: Jeong Kuk KIM, Yongin-si (KR); Young Min MOON, Yongin-si (KR); Jun Ho JO, Yongin-si (KR)

(73) Assignee: Samsung Display Co., LTD., Yongin-si (KR)

(21) Appl. No.: 18/734,300

(22) Filed: Jun. 5, 2024

(30) Foreign Application Priority Data
Sep. 26, 2023 (KR) 10-2023-0128901

(51) Int. Cl. C23C 14/04; C25D 5/02; C25D 5/54; H10K 59/12

(52) U.S. Cl. CPC C23C 14/042; C25D 5/022; C25D 5/54; H10K 59/12

(57) ABSTRACT

A method of fabricating a mask includes defining cell areas and a mask frame area on a silicon substrate, the mask frame area excluding the cell areas, the mask frame area may include a mask rib region partitioning the cell areas and an outer frame region disposed at an outermost position of the silicon substrate, forming a groove in the mask rib region, forming a metal mask rib by forming a metal in the groove, forming a photoresist pattern including openings in each of the cell areas, growing a plating film in each of the cell areas, forming a mask membrane formed of the plating film by removing the photoresist pattern, and etching a rear surface of the silicon substrate to form cell openings associated with the cell areas, respectively.

### CROSS-REFERENCE TO RELATED APPLICATION(S)

This application claims priority to and benefits of Korean Patent Application No. 10-2023-0128901 under 35 U.S.C. § 119 filed on Sep. 26, 2023 in the Korean Intellectual Property Office, the entire contents of which are incorporated herein by reference.

### BACKGROUND

### 1. Technical Field

The disclosure relates to a mask for deposition and a method of fabricating the same.

### 2. Description of the Related Art

A wearable device is being developed which is in the form of glasses or a helmet and forms a focus at a location close to the user's eyes. For example, a wearable device may be a head mounted display (HMD) device or an AR glass. Such a wearable device provides a user with an augmented reality (hereinafter referred to as “AR”) screen or a virtual reality (hereinafter referred to as “VR”) screen.

A wearable device such as a HMD device and AR glasses require display specifications of at least 2,000 PPI (pixels per inch) to allow users to use it for a long time without dizziness. To this end, an organic light-emitting diode on silicon (OLEDoS) technology is emerging, which is a high-resolution small organic light-emitting element display device. The OLEDoS is a technology for disposing organic light-emitting diodes (OLEDs) on a semiconductor wafer substrate on which a complementary metal oxide semiconductor (CMOS) is disposed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects provide a method of fabricating a deposition mask that can prevent sagging of the mask by applying magnetic metal to a mask rib.

According to an embodiment, a method of fabricating a mask may include defining a plurality of cell areas and a mask frame area on a silicon substrate, the mask frame area excluding the plurality of cell areas, wherein the mask frame area may include a mask rib region partitioning the plurality of cell areas and an outer frame region disposed at an outermost position of the silicon substrate; forming a groove in the mask rib region; forming a metal mask rib by forming a metal in the groove; forming a photoresist pattern including a plurality of first openings in each of the plurality of cell areas, growing a plating film in each of the plurality of cell areas; forming a mask membrane formed of the plating film by removing the photoresist pattern, and etching a rear surface of the silicon substrate to form cell openings associated with the plurality of cell areas, respectively.

A cross-section of the mask membrane may have a substantially reverse taper shape in which a width becomes narrower from a front side of the silicon substrate toward a rear side of the silicon substrate.

A thickness of the metal mask rib may be greater than a thickness of the mask membrane.

The mask membrane may include mask shadows formed by the plating film, and mask openings disposed between adjacent mask shadows.

A cross-section of the mask openings may have a substantially taper shape in which a width becomes wider from a front side of the silicon substrate toward a rear side of the silicon substrate.

The plating film may contain tungsten (W).

The plating film may contain copper (Cu).

According to an embodiment, a method of fabricating a mask may include defining a plurality of cell areas and a mask frame area on a silicon substrate, the mask frame area excluding the plurality of cell areas, wherein the mask frame area may include a mask rib region partitioning the plurality of cell areas and an outer frame region disposed at an outermost position of the silicon substrate; forming a groove in the mask rib region; forming a metal mask rib by forming a metal in the groove; forming an inorganic film in each of the plurality of cell areas; forming a photoresist pattern including a plurality of first openings on the inorganic film; forming a mask membrane by etching a portion of the inorganic film using the photoresist pattern; removing the photoresist pattern; and etching a rear surface of the silicon substrate to form cell openings associated with the plurality of cell areas, respectively.

A cross-section of the mask membrane may have a substantially reverse taper shape in which a width becomes narrower from a front side of the silicon substrate toward a rear side of the silicon substrate.

A thickness of the metal mask rib may be greater than a thickness of the mask membrane.

The mask membrane may include mask shadows formed by a plating film, and mask openings disposed between adjacent mask shadows.

A cross-section of the mask openings may have a substantially taper shape in which a width becomes wider from a front side of the silicon substrate toward a rear side of the silicon substrate.

According to an embodiment, a deposition mask may include a silicon substrate including a plurality of cell areas and a mask frame area excluding the plurality of cell areas, wherein the mask frame area may include a mask rib region partitioning the plurality of cell areas and an outer frame region disposed at an outermost position of the silicon substrate; a metal mask rib disposed in the mask rib region, and a mask membrane disposed in each of the plurality of cell areas.

The mask membrane may be formed by a plating film disposed on the silicon substrate.

The plating film may contain tungsten (W).

The plating film may contain copper (Cu).

The mask membrane may be formed by an inorganic film disposed on the silicon substrate.

A cross-section of the mask membrane may have a substantially reverse taper shape in which a width becomes narrower from a front side of the silicon substrate toward a rear side of the silicon substrate.

A thickness of the metal mask rib may be greater than a thickness of the mask membrane.

Each of the plurality of cell areas may include a cell opening exposing the mask membrane as a rear surface of the silicon substrate is etched.

According to embodiments, it is possible to prevent sagging of a deposition mask by applying magnetic metal to a mask rib. It is possible to increase the alignment accuracy of the mask and to prevent mura defects caused by sagging of the mask.

However, aspects are not restricted to those set forth herein. The above and other aspects will become more apparent to one of ordinary skill in the art to which the disclosure pertains by referencing the detailed description of the disclosure given below.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a head-mounted display device according to an embodiment.

FIG. 2 is an exploded perspective view of an example of the head-mounted display device of FIG. 1.

FIG. 3 is a schematic perspective view of a head-mounted display device according to an embodiment.

FIG. 4 is an exploded perspective view showing a display device according to an embodiment.

FIG. 5 is a schematic cross-sectional view showing an example of a part of a display panel according to an embodiment.

FIG. 6 is a schematic perspective view of a mask according to an embodiment.

FIG. 7 is a schematic plan view of a mask according to an embodiment.

FIG. 8 is a flowchart for illustrating a method of fabricating a mask according to an embodiment.

FIGS. 9 to 14 are schematic cross-sectional views for illustrating processing steps of the method of fabricating a mask according to an embodiment.

FIG. 15 is a flowchart for illustrating a method of fabricating a mask according to an embodiment.

FIGS. 16 to 21 are schematic cross-sectional views of processing steps for illustrating a method of fabricating the mask shown in FIG. 15.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Features of each of various embodiments may be partially or entirely combined with each other and may technically variously interwork with each other, and respective embodiments may be implemented independently of each other or may be implemented together in association with each other.

Hereinafter, embodiments will be described with reference to the accompanying drawings.

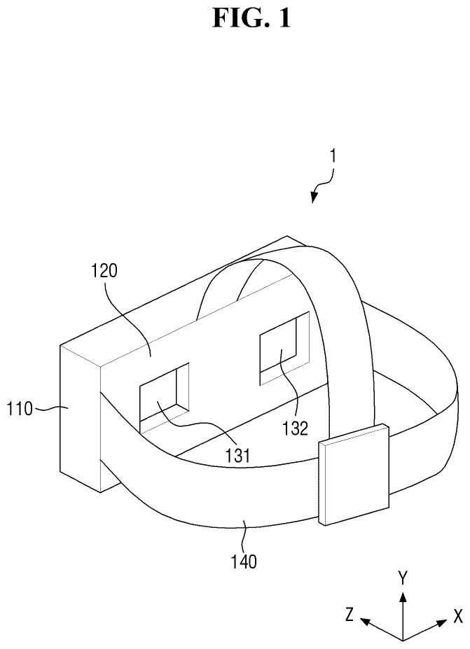

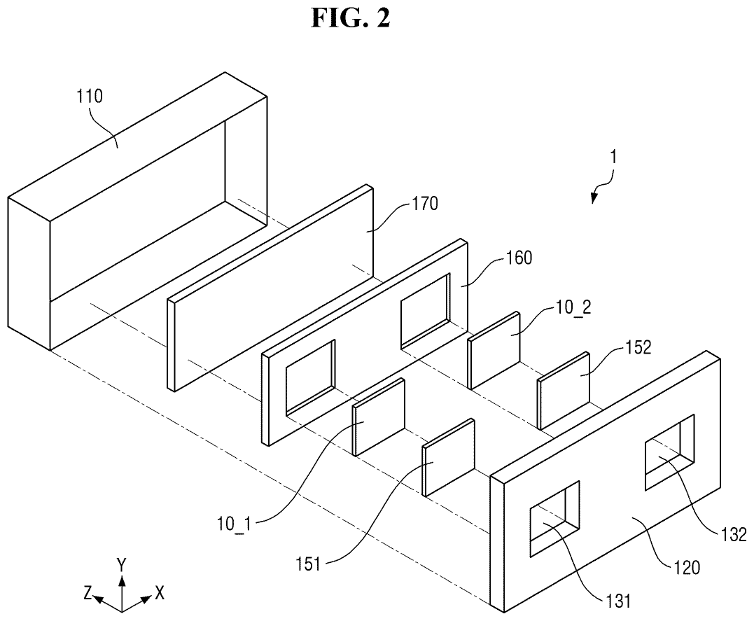

FIG. 1 is a schematic perspective view of a head-mounted display device according to an embodiment. FIG. 2 is an exploded perspective view of an example of the head-mounted display device of FIG. 1.

Referring to FIGS. 1 and 2, a head-mounted display device 1 according to an embodiment may include a first display device 10_1, a second display device 10_2, a display device housing 110, and a housing cover 120, a first eyepiece 131, a second eyepiece 132, a head strap band 140, a middle frame 160, a first optical member 151, a second optical member 152, a control circuit board 170, and a connector. FIGS. 1 and 2 illustrate a first direction, X, a second direction Y, and a third direction, Z.

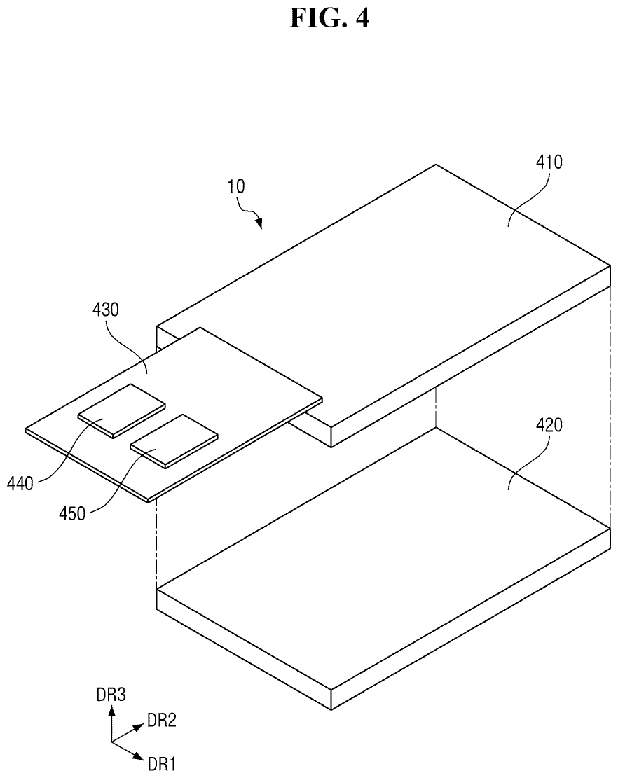

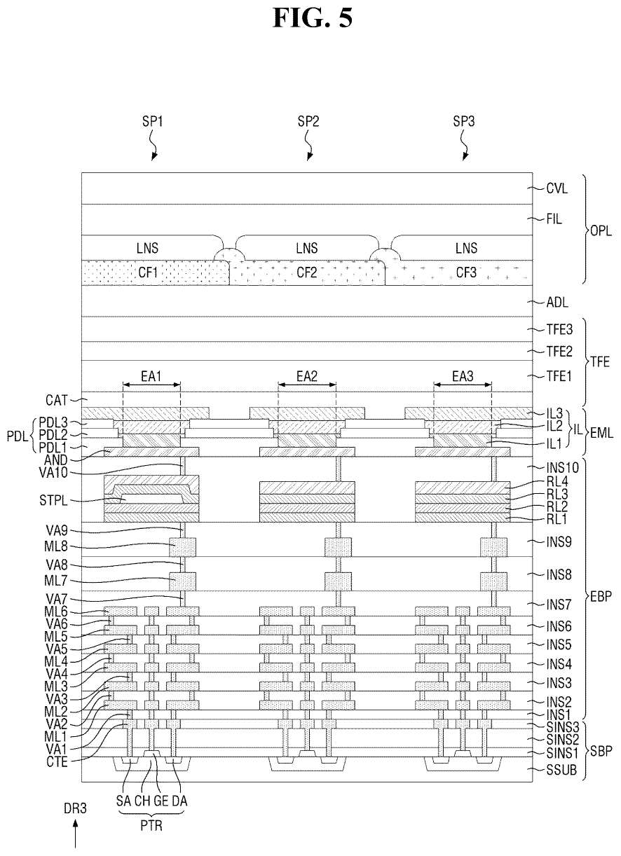

The first display device 10_1 provides images to a user's left eye, and the second display device 10_2 provides images to the user's right eye. Each of the first display device 10_1 and the second display device 10_2 is substantially identical to the display device 10 described with reference to FIGS. 4 and 5. Therefore, descriptions of the first display device 10_1 and the second display device 10_2 will be replaced with descriptions referring to FIGS. 4 and 5.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2 and the control circuit board 170.

The control circuit board 170 may be disposed between the middle frame 160 and the display device housing 110. The control circuit board 170 may be connected to the first display device 10_1 and the second display device 10_2 through a connector. The control circuit board 170 may convert an image source input from the outside into digital video data (DATA) and may transmit the digital video data (DATA) to the first display device 10_1 and the second display device 10_2 through the connector.

The control circuit board 170 may transmit digital video data (DATA) associated with a left eye image optimized for the user's left eye to the first display device 10_1, and may transmit digital video data (DATA) associated with a right eye image optimized for the user's right eye to the second display device 10_2. By way of example, the control circuit board 170 may transmit the same digital video data (DATA) to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 is disposed to cover the open face of the housing 110. The housing cover 120 may include the first eyepiece 131 where the user's left eye is placed, and the second eyepiece 132 where the user's right eye is placed. Although the first eyepiece 131 and the second eyepiece 132 are separately disposed in the example shown in FIGS. 1 and 2, embodiments are not limited thereto. The first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images of images on the first display device 10_1 magnified by the first optical member 151 through the first eyepiece 131, and virtual images of images on the second display device 10_2 magnified by the second optical member 152 through the second eyepiece 132.

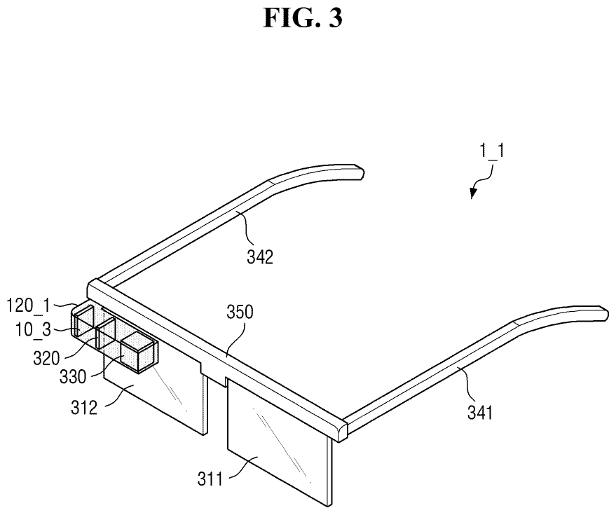

The head strap band 140 fixes the housing 110 to the user's head so that the first eyepiece 131 and the second eyepiece 132 of the housing cover 120 remain in line with the user's left and right eyes, respectively. By implementing a light and small display device housing 120, the head-mounted display device 1 may include an eyeglasses frame as shown in FIG. 3 instead of a head strap band 140.

The head-mounted display device 1 may further include a battery for supplying power, an external memory slot for inserting an external memory, and an external connection port and a wireless communication module for receiving an image source. The external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module.

FIG. 3 is a schematic perspective view of a head-mounted display device according to an embodiment.

Referring to FIG. 3, the head-mounted display device 1_1 according to the embodiment may be a glasses-type display device with a light and small display device housing 120_1. The head-mounted display device 1_1 according to the embodiment may include display devices 10_3, a left-eye lens 311, a right-eye lens 312, a support frame 350, eyeglass temples 341 and 342, optical members 320, optical path conversion members 330, and display device housings 120_1.

The display device 10_3 shown in FIG. 3 is substantially identical to the display device 10 described with reference to FIGS. 4 and 5. Therefore, descriptions of the first display device 10_1 and the second display device 10_2 will be replaced with descriptions referring to FIGS. 4 and 5.

The display device housings 120_1 may include the display devices 10_3, the optical members 320, and the optical path conversion members 330. The images displayed on the display device 10_3 may be enlarged by the optical member 320, and the optical paths of the images are converted by the optical path conversion member 330 to be provided to the user's right eye through the right eye lens 312. As a result, the user can see, with the right eye, augmented reality images that combine virtual images displayed on the display device 10_3 and real world images viewed through the right eye lens 312.

Although the display device housing 120_1 is disposed at the right end of the support frame 350 in the example shown in FIG. 3, embodiments are not limited thereto. For example, the display device housing 120_1 may be disposed at the left end of the support frame 350. In such case, images displayed on the display device 10_3 may be provided to the user's left eye. By way of example, the display device housing 120_1 may be disposed at both the left and right ends of the support frame 350, respectively. In such case, the user can watch images displayed on the display device 10_3 through both the left and right eyes.

FIG. 4 is an exploded perspective view showing a display device according to an embodiment.

Referring to FIG. 4, the display device 10 according to the embodiment displays a moving image or a still image. The display device 10 according to the embodiment may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). By way of example, the display device 10 may be applied to a smart watch, a watch phone, or a head-mounted display (HMD) for implementing virtual reality and augmented reality.

According to an embodiment, the display device 10 may include a display panel 410, a heat dissipation layer 420, a circuit board 430, a driver circuit 440, and a power supply circuit 450.

The display panel 410 may have a shape similarly to a rectangular shape when viewed from the top. For example, the display panel 410 may have a shape similar to a rectangle having shorter sides in the first direction DR1 and longer sides in the second direction DR2 intersecting the first direction DR1 when viewed from the top. In the display panel 410, the corners where the shorter sides in the first direction DR1 meet the longer sides in the second direction DR2 may be rounded with a selectable curvature or may be a right angle. The shape of the display panel 410 when viewed from the top is not limited to a rectangular shape, but may be formed in a shape similar to other polygonal shapes, a circular shape, or an elliptical shape. The shape of the display device 10 may follow the shape of the display panel 410 when viewed from the top, but embodiments are not limited thereto.

The display panel 410 may include a display area where images are displayed, and a non-display area where no image is displayed.

The display area may include a plurality of pixels, and each of the plurality of pixels may include a plurality of sub-pixels SP1, SP2 and SP3 (see FIG. 5). The sub-pixels SP1, SP2 and SP3 include a plurality of pixel transistors. The pixel transistors are formed via a semiconductor process and may be disposed on a semiconductor substrate SSUB (see FIG. 5). For example, the pixel transistors may be implemented as complementary metal oxide semiconductor (CMOS).

The heat dissipation layer 420 may overlap the display panel 410 in the third direction DR3, which is the thickness direction of the display panel 410. The heat dissipation layer 420 may be disposed on one surface or a surface of the display panel 410, for example, on the rear surface. The heat dissipation layer 420 serves to discharge heat generated in the display panel 410. The heat dissipation layer 420 may include a metal layer such as graphite, silver (Ag), copper (Cu) and aluminum (Al) having a high thermal conductivity.

The circuit board 430 may be electrically connected to a plurality of pads PD in a pad area PDA of the display panel 410 using a conductive adhesive member such as an anisotropic conductive film. The circuit board 430 may be a flexible printed circuit board made of a flexible material, or a flexible film. Although the circuit board 430 is unfolded in FIG. 4, the circuit board 430 may be bent. In case that it is bent, one end or an end of the circuit board 430 may be disposed on the rear surface of the display panel 410. The one end of the circuit board 430 may be opposite to the opposite end of the circuit board 430, which is connected to the pads PD in the pad area PDA of the display panel 410 using a conductive adhesive member.

The driver circuit 440 may receive digital video data and timing signals from the outside. The driver circuit 440 may generate a scan timing control signal, an emission timing control signal, and a data timing control signal for controlling the display panel 410 in response to the timing signals.

The power supply circuit 450 may generate a plurality of panel driving voltages in response to a supply voltage from the outside. For example, the power supply circuit 450 may generate a first supply voltage (for example, voltage VSS), a second supply voltage (for example, voltage VDD), and a third supply voltage (for example, voltage VINT) to apply them to the display panel 410.

Each of the driver circuit 440 and the power supply circuit 450 may be implemented as an integrated circuit (IC) and attached to a surface of the circuit board 430.

FIG. 5 is a schematic cross-sectional view showing an example of a part of a display panel according to an embodiment. For example, FIG. 5 shows a cross-sectional structure of a part of a display area that may include a plurality of sub-pixels SP1, SP2 and SP3 (see FIG. 5).

Referring to FIG. 5, the display panel 410 may include a semiconductor backplane SBP, an emission material backplane EBP, an emission material layer EML, an encapsulation layer TFE, an optical layer OPL, a cover layer CVL, and a polarizer (not shown).

The semiconductor backplane SBP may include a semiconductor substrate SSUB including a plurality of pixel transistors PTR, a plurality of semiconductor insulating films covering the plurality of pixel transistors PTR, and a plurality of contact terminals CTE that are electrically connected to the pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be located (or disposed) in the upper surface of the semiconductor substrate SSUB. The well areas WA may be doped with second-type impurities. The second-type impurities may be different from the first-type impurities. For example, in case that the first-type impurities are p-type impurities, the second-type impurities may be n-type impurities. By way of example, in case that the first-type impurities are n-type impurities, the second-type impurities may be p-type impurities.

Each of the well areas WA may include a source region SA associated with a source electrode of a pixel transistor PTR, a drain region DA associated with a drain electrode thereof, and a channel region CH between the source region SA and the drain region DA.

Each of the source region SA and the drain region DA may be doped with the first-type impurities. The gate electrode GE of the pixel transistor PTR may overlap the well area WA in the third direction DR3. The channel region CH may overlap the gate electrode GE in the third direction DR3. The source area SA may be located on one side or a side of the gate electrode GE, and the drain area SA may be located on the opposite side of the gate electrode GE.

Each of the plurality of well areas WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may have a lower impurity concentration than the source region SA. The second low-concentration impurity region LDD2 may have a lower impurity concentration than the drain region DA. The distance between the source region SA and the drain region DA may be increased by the first low-concentration impurity region LDD1 and the second low-concentration impurity region LDD2. Therefore, the length of the channel region CH of each of the pixel transistors PTR can be increased, and thus it is possible to prevent punch-through and hot carrier phenomenon due to short channel.

A first semiconductor insulating film SINS1 may be disposed on the semiconductor substrate SSUB. The first semiconductor insulating film SINS1 may be formed of, but is not limited to, a silicon carbon nitride (SiCN) or a silicon oxide (SiOₓ)-based inorganic film.

A second semiconductor insulating film SINS2 may be disposed on the first semiconductor insulating film SINS1. The second semiconductor insulating film SINS2 may be formed of a silicon oxide (SiOₓ)-based inorganic film, but embodiments are not limited thereto.

A plurality of contact terminals CTE may be disposed on the second semiconductor insulating film SINS2. Each of the plurality of contact terminals CTE may be connected to one of the gate electrode GE, the region SA and the drain region DA of each of the pixel transistors PTR through a hole penetrating the first semiconductor insulating film SINS1 and the second semiconductor insulating film INS2. The contact terminals CTE may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

A third semiconductor insulating film SINS3 may be disposed on the side surface of each of the contact terminals CTE. The upper surface of each of the contact terminals CTE may not be covered by the third semiconductor insulating film SINS3 but may be exposed. The third semiconductor insulating film SINS3 may be formed of a silicon oxide (SiOₓ)-based inorganic film, but embodiments are not limited thereto.

The semiconductor substrate SSUB may be replaced with a glass substrate or a polymer resin substrate such as polyimide. In this instance, thin-film transistors may be disposed on a glass substrate or a polymer resin substrate. The glass substrate may be a rigid substrate that is not bent, while the polymer resin substrate may be a flexible substrate that can be bent or curved.

The emission material backplane EBP may include first to eighth metal layers ML1 to ML8, reflective metal layers RL1 to RL4, a plurality of vias VA1 to VA10, and a step layer STPL. The emission material backplane EBP may include a plurality of interlayer dielectric films INS1 to INS10 disposed between the first to sixth metal layers ML1 to ML6.

The first to eighth metal layers ML1 to ML8 serve to implement a circuit of a first sub-pixel SP1 by connecting a plurality of contact terminals CTE exposed from the semiconductor backplane SBP.

The first interlayer insulating film INS1 may be disposed on the semiconductor backplane SBP. Each of the first vias VA1 may penetrate the first interlayer dielectric film INS1 and may be connected to the contact terminal CTE exposed from the semiconductor backplane SBP. Each of the first metal layers ML1 may be disposed on the first interlayer insulating film INS1 and may be connected to the first via VA1.

The second interlayer dielectric film INS2 may be disposed on the first interlayer dielectric film INS1 and the first metal layers ML1. Each of the second vias VA2 may penetrate through the second interlayer dielectric film INS2 to be connected to the exposed first metal layer ML1. Each of the second metal layers ML2 may be disposed on the second interlayer insulating film INS2 and may be connected to the second via VA2.

The third interlayer dielectric film INS3 may be disposed on the second interlayer dielectric film INS2 and the second metal layers ML2. Each of the third vias VA3 may penetrate through the third interlayer dielectric film INS3 to be connected to the exposed second metal layer ML2. Each of the third metal layers ML3 may be disposed on the third interlayer insulating film INS3 and may be connected to the third via VA3.

The fourth interlayer dielectric film INS4 may be disposed on the third interlayer dielectric film INS3 and the third metal layers ML3. Each of the fourth vias VA2 may penetrate through the fourth interlayer dielectric film INS4 to be connected to the exposed third metal layer ML3. Each of the fourth metal layers ML4 may be disposed on the fourth interlayer insulating film INS4 and may be connected to the fourth via VA4.

The fifth interlayer dielectric film INS5 may be disposed on the fourth interlayer dielectric film INS4 and the fourth metal layers ML4. Each of the fifth vias VA5 may penetrate through the fifth interlayer dielectric film INS5 to be connected to the exposed fourth metal layer ML4. Each of the fifth metal layers ML5 may be disposed on the fifth interlayer insulating film INS5 and may be connected to the fifth via VA5.

The sixth interlayer dielectric film INS6 may be disposed on the fifth interlayer dielectric film INS5 and the fifth metal layers ML5. Each of the sixth vias VA6 may penetrate through the sixth interlayer dielectric film INS6 to be connected to the exposed fifth metal layer ML5. Each of the sixth metal layers ML6 may be disposed on the sixth interlayer insulating film INS6 and may be connected to the sixth via VA6.

The seventh interlayer dielectric film INS7 may be disposed on the sixth interlayer dielectric film INS6 and the sixth metal layers ML6. Each of the seventh vias VA7 may penetrate through the seventh interlayer dielectric film INS7 to be connected to the exposed sixth metal layer ML6. Each of the seventh metal layers ML7 may be disposed on the seventh interlayer insulating film INS7 and may be connected to the seventh via VA7.

The eighth interlayer dielectric film INS8 may be disposed on the seventh interlayer dielectric film INS7 and the seventh metal layers ML7. Each of the eighth vias VA8 may penetrate through the eighth interlayer dielectric film INS8 to be connected to the exposed seventh metal layer ML7. Each of the eighth metal layers ML8 may be disposed on the eighth interlayer insulating film INS8 and may be connected to the eighth via VA8.

The first to eighth metal layers ML1 to ML8 and the first to eighth vias VA1 to VA8 may be made of substantially the same material. The first to eighth metal layers ML1 to ML8 and the first to eighth vias VA1 to VA8 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. The first to eighth vias VA1 to VA8 may be made of substantially the same material. The first to eighth interlayer dielectric films INS1 to INS8 may be formed of a silicon oxide (SiOₓ)-based inorganic film, but embodiments are not limited thereto.

The thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6 may be greater than the thickness of the first via VA1, the thickness of the second via VA2, the thickness of the third via VA3, the thickness of the fourth via VA4, the thickness of the fifth via VA5 and the thickness of the sixth via VA6. The thickness of the second metal layer ML2, the thickness of the third metal layer ML3, the thickness of the fourth metal layer ML4, the thickness of the fifth metal layer ML5, and the thickness of the sixth metal layer ML6 may be greater than the thickness of the first metal layer ML1. The thickness of the second metal layer ML2, the thickness of the third metal layer ML3, the thickness of the fourth metal layer ML4, the thickness of the fifth metal layer ML5 and the thickness of the sixth metal layer ML6 may be substantially all equal.

The thickness of the seventh metal layer ML7 and the thickness of the eighth metal layer ML8 may be greater than the thickness of the first metal layer ML1, the thickness of the second metal layer ML2, the thickness of the third metal layer ML3, the thickness of the fourth metal layer ML4, the thickness of the fifth metal layer ML5 and the thickness of the sixth metal layer ML6. The thickness of the seventh metal layer ML7 and the thickness of the eighth metal layer ML8 may be greater than the thickness of the seventh via VA7 and the thickness of the eighth via VA8. The thickness of the seventh via VA7 and the thickness of the eighth via VA8 may be greater than the thickness of the first via VA1, the thickness of the second via VA2, the thickness of the third via VA3, and the thickness of the fourth via VA4, the thickness of the fifth via VA5 and the thickness of the sixth via VA6. The thickness of the seventh metal layer ML7 may be substantially equal to the thickness of the eighth metal layer ML8.

The ninth interlayer dielectric film INS9 may be disposed on the eighth interlayer dielectric film INS8 and the eighth metal layers ML8. The ninth interlayer dielectric film INS9 may be formed of a silicon oxide (SiOₓ)-based inorganic film, but embodiments are not limited thereto.

Each of the ninth vias VA9 may penetrate through the ninth interlayer dielectric film INS9 to be connected to the exposed eighth metal layer ML8. The ninth vias VA9 may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

The first reflective electrodes RL1 may be disposed on the ninth interlayer dielectric film INS9 and may be connected to the ninth via VA9. The first reflective electrodes RL1 may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

The second reflective electrodes RL2 may be disposed on the first reflective electrodes RL1. The second reflective electrodes RL2 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the second reflective electrodes RL2 may be titanium nitride (TiN).

In the first sub-pixel SP1, a step layer STPL may be disposed on the second reflective electrode RL2. No step layer STPL may be disposed in each of the second sub-pixel SP2 and the third sub-pixel SP3. The thickness of the step layer STPL may be determined based on the wavelength of the light of a first color and the distance from a first emissive layer EML1 to a fourth reflective electrode RL4 so that the light of the first color emitted from the first emissive layer EML1 of the first sub-pixel SP1 is advantageously reflected. The step layer STPL may be formed of, but is not limited to, a silicon carbon nitride (SiCN) or a silicon oxide (SiOₓ)-based inorganic film.

In the first sub-pixel SP1, the third reflective electrode RL3 may be disposed on the second reflective electrode RL2 and the step layer STPL. In the second sub-pixel SP2 and the third sub-pixel SP3, the third reflective electrode RL3 may be disposed on the second reflective electrode RL2. The third reflective electrodes RL3 may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

At least one of the first reflective electrode RL1, the second reflective electrode RL2 and the third reflective electrode RL3 may be eliminated.

The fourth reflective electrodes RL4 may be disposed on the third reflective electrodes RL3. The fourth reflective electrodes RL4 may reflect lights from the first to third intermediate layers EML1, EML2 and EML3. The fourth reflective electrodes RL4 may include a metal with high reflectivity to be advantageous for light reflection. The fourth reflective electrodes RL4 may be made up of, but is not limited to, aluminum (Al), a stack of aluminum and titanium (Ti/Al/Ti), a stack of aluminum and ITO (ITO/Al/ITO), silver (Ag), palladium (Pd), and an APC alloy, which is an alloy of copper (Cu), and a stack of an APC alloy and ITO (ITO/APC/ITO).

The tenth interlayer dielectric film INS10 may be disposed on the ninth interlayer dielectric film INS9 and the fourth reflective electrodes RL4. The tenth interlayer dielectric film INS10 may be formed of a silicon oxide (SiOₓ)-based inorganic film, but embodiments are not limited thereto.

Each of the tenth vias VA10 may penetrate through the tenth interlayer dielectric film INS10 to be connected to the exposed ninth metal layer ML9. The tenth vias VA10 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. Due to the step layer STPL, the thickness of the tenth via VA10 in the first sub-pixel SP1 may be smaller than the thickness of the tenth via VA10 in each of the second sub-pixel SP2 and the third sub-pixel SP3.

The emission material layer EML may be disposed on the emission material backplane EBP. The emission material layer EML may include light-emitting elements LEL each including a first electrode AND, an intermediate layer IL and a second electrode CAT, and a pixel-defining film PDL.

The first electrode AND of each of the light-emitting elements LEL may be disposed on the tenth interlayer dielectric film INS10 and may be connected to the tenth via VA10. The first electrode AND of each of the light-emitting elements LEL may be connected to the drain region DA or the source region SA of the pixel transistor PTR through the tenth via VA10, the first to fourth reflective electrodes RL1 to RL4, the first to ninth vias VA1 to VA9, the first to eighth metal layers ML1 to ML8 and the contact terminals CTE. The first electrode AND of each of the light-emitting elements LEL may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the first electrode AND of each of the light-emitting elements LEL may be titanium nitride (TiN).

The pixel-defining film PDL may be disposed partially on the first electrode AND of each of the light-emitting elements LE. The pixel-defining film PDL may cover the edge of the first electrode AND of each of the light-emitting elements LE. The pixel-defining film PDL serves to partition the first emission areas EA1, the second emission areas EA2 and the third emission areas EA3.

A first emission area EA1 may be defined as an area in the first sub-pixel SP1 where the first electrode AND, the intermediate layer IL and the second electrode CAT may be sequentially stacked each other to emit light. A second emission area EA2 may be defined as an area in the second sub-pixel SP2 where the first electrode AND, the intermediate layer IL and the second electrode CAT may be sequentially stacked each other to emit light. A third emission area EA3 may be defined as an area in the third sub-pixel SP3 where the first electrode AND, the intermediate layer IL and the second electrode CAT may be sequentially stacked each other to emit light.

The pixel-defining film PDL may include first to third pixel-defining films PDL1, PDL2 and PDL3. The first pixel-defining film PDL1 may be disposed on the edge of the first electrode AND of each of the light-emitting elements LE, the second pixel-defining film PDL2 may be disposed on the first pixel-defining film PDL1, and the third pixel-defining film PDL3 may be disposed on the second pixel-defining film PDL2. The first pixel-defining film PDL1, the second pixel-defining film PDL2 and the third pixel-defining film PDL3 may be formed of a silicon oxide (SiOₓ)-based inorganic film, but embodiments are not limited thereto.

The intermediate layer IL may include a first intermediate layer IL1, a second intermediate layer IL2, and a third intermediate layer IL3.

The intermediate layer IL may have a tandem structure including a plurality of intermediate layers IL1, IL2 and IL3 that emit different lights. For example, the intermediate layer IL may include the first intermediate layer IL1 that emits light of the first color, the second intermediate layer IL2 that emits light of the third color, and the third intermediate layer IL3 that emits light of the second color. The first intermediate layer IL1, the second intermediate layer IL2 and the third intermediate layer IL3 may be sequentially stacked each other.

The first intermediate layer IL1 may have a structure in which a first hole transport layer, a first organic emissive layer that emits light of the first color, and a first electron transport layer may be sequentially stacked each other. The second intermediate layer IL2 may have a structure in which a second hole transport layer, a second organic emissive layer that emits light of the third color, and a second electron transport layer may be sequentially stacked each other. The third intermediate layer IL3 may have a structure in which a third hole transport layer, a third organic emissive layer that emits light of the second color, and a third electron transport layer may be sequentially stacked each other.

The intermediate layer IL may cover the first electrode AND at an opening of the pixel-defining film PDL, may cover the pixel-defining film PDL between adjacent sub-pixels SP1, SP2 and SP3, and may be partially disconnected.

According to the embodiment, it is possible to prevent leakage current between adjacent sub-pixel SP1, SP2 and SP3 and to prevent color crosstalk by disconnecting the intermediate layer IL between the adjacent sub-pixel SP1, SP2 and SP3. The color crosstalk refers to, for example, a phenomenon that a red sub-pixel adjacent to a blue sub-pixel is unintentionally turned on while the blue sub-pixel emits blue light. Since color crosstalk occurs due to leakage current, it may occur if a blue sub-pixel and a red sub-pixel are adjacent to each other, which have a large difference in voltage for driving the sub-pixels. For example, while the driving current is supplied to the light-emitting element LEL of a blue sub-pixel in order to turn on the blue sub-pixel, a part of the driving current may be transmitted to a red sub-pixel through at least some conductive layers of the intermediate IL, which is leakage current. If leakage current is generated, the red sub-pixel may be unintentionally turned on while the blue sub-pixel is turned on.

The number of intermediate layers IL1, IL2 and IL3 emitting different lights is not limited to that shown in FIG. 5. For example, the intermediate layer IL may include two intermediate layers. In this instance, one of the two intermediate layers is substantially identical to the first intermediate layer IL1, and the other one may include a second hole transport layer, a second organic emissive layer, a third organic emissive layer, and a second electron transport layer. In this instance, a charge generation layer may be disposed between the two intermediate layers to supply electrons to one intermediate layer and to supply charges to the other intermediate layer.

Although the first to third intermediate layers IL1, IL2 and IL3 are all disposed in the first emission area EA1, the second emission area EA2 and the third emission area EA3 in FIG. 5, embodiments are not limited thereto. For example, the first intermediate layer IL1 may be disposed in the first emission area EA1 but not in the second emission area EA2 and the third emission area EA3. The second intermediate layer IL2 may be disposed in the second emission area EA2 but not in the first emission area EA1 and the third emission area EA3. The third intermediate layer IL3 may be disposed in the third emission area EA3 but not in the first emission area EA1 and the second emission area EA2. In this instance, the first to third color filters CF1, CF2 and CF3 of the optical layer OPL may be eliminated.

The second electrode CAT may be disposed on the third intermediate layer IL3. The second electrode CAT may be disposed on the third intermediate layer IL3 in each of a plurality of trenches TRC. The second electrode CAT may be formed of a transparent conductive material (TCP) such as ITO and IZO that can transmit light, or a semi-transmissive conductive material such as magnesium (Mg), silver (Ag) and an alloy of magnesium (Mg) and silver (Ag). In case that the second electrode CAT is formed of a semi-transmissive conductive material, the light extraction efficiency can be increased by using microcavities in each of the first to third sub-pixels SP1, SP2 and SP3.

The encapsulation layer TFE may be disposed on the emission material layer EML. The encapsulation layer TFE may include one or more inorganic films TFE1 and TFE2 to prevent permeation of oxygen or moisture into the emission material layer EML. The encapsulation layer TFE may include at least one organic film to protect the emission material layer EML from particles such as dust. For example, the encapsulation layer TFE may include a first inorganic encapsulation film TFE1, an organic encapsulation film TFE2 and a second inorganic encapsulation film TFE3.

The first inorganic encapsulation film TFE1 may be disposed on the second electrode CAT, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer (SiNₓ), a silicon oxynitride layer (SiON), a silicon oxide layer (SiOₓ), a titanium oxide layer (TiOₓ) and an aluminum oxide layer (AlOₓ) are alternately stacked each other. The organic encapsulation film TFE2 may be a monomer. By way of example, the organic encapsulation film TFE2 may be an organic film such as an acryl resin, an epoxy resin, a phenolic resin, a polyamide resin, a polyimide resin, etc.

An adhesive layer ADL may adhere the encapsulation layer TFE to the optical layer OPL. The adhesive layer ADL may be a double-sided adhesive member. The adhesive layer ADL may be a transparent adhesive member such as a transparent adhesive and a transparent adhesive resin.

The optical layer OPL may include a plurality of color filters CF1, CF2 and CF3, a plurality of lenses LNS, and a filling layer FIL. The plurality of color filters CF1, CF2 and CF3 may include first to third color filters CF1, CF2 and CF3. The first to third color filters CF1, CF2 and CF3 may be disposed on the adhesive layer ADL.

The first color filter CF1 may be in line with the first emission area EA1 of the first sub-pixel SP1. The first color filter CF1 may transmit light of the first color, for example, light in the blue wavelength range. The blue wavelength range may be in a range of about 370 nm to about 460 nm. Therefore, the first color filter CF1 may transmit light of the first color among the lights emitted from the first emission area EA1.

The second color filter CF2 may be in line with the second emission area EA2 of the second sub-pixel SP2. The second color filter CF2 may transmit light of the second color, for example, light in the green wavelength range. The green wavelength range may be in a range of about 480 nm to about 560 nm. Therefore, the second color filter CF2 may transmit light of the second color among the lights emitted from the second emission area EA2.

The third color filter CF3 may be in line with the third emission area EA3 of the third sub-pixel SP3. The third color filter CF3 may transmit light of the third color, for example, light in the red wavelength range. The blue wavelength range may be in a range of about 600 nm to about 750 nm. Therefore, the third color filter CF3 may transmit light of the third color among the lights emitted from the third emission area EA3.

The lenses LNS may be disposed on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is convex upward.

The filling layer FIL may be disposed on a plurality of lenses LNS. The filling layer FIL may have a selectable refractive index so that light travels in the third direction DR3 at the interface between the plurality of lenses LNS and the filling layer FIL. The filling layer FIL may be a planarization layer. The filling layer FIL may be an organic film such as an acryl resin, an epoxy resin, a phenolic resin, a polyamide resin, and a polyimide resin.

The cover layer CVL may be disposed on the filling layer FIL. The cover layer CVL may be a glass substrate or a polymer resin such as a resin. If the cover layer CVL is a glass substrate, it may be attached to the filling layer FIL. In this instance, the filling layer FIL may adhere the cover layer CVL. If the cover layer CVL is a glass substrate, it may work as an encapsulation substrate. If the cover layer CVL is a polymer resin such as a resin, it may be applied directly on the filling layer FIL.

A polarizer (not shown) may be disposed on a surface of the cover layer CVL. The polarizer may be a structure for preventing deterioration of visibility due to reflection of external light. The polarizer may include a linear polarizer and a retardation film. For example, the retardation film may be a λ/4 plate (quarter-wave plate), but embodiments are not limited thereto. If visibility is sufficiently improved by the first to third color filters CF1, CF2 and CF3 regardless of reflection of external light, the polarizer may be eliminated.

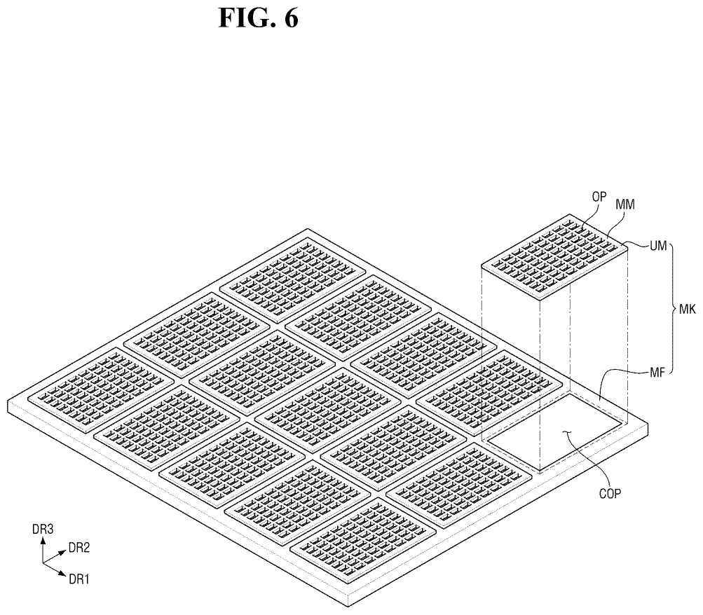

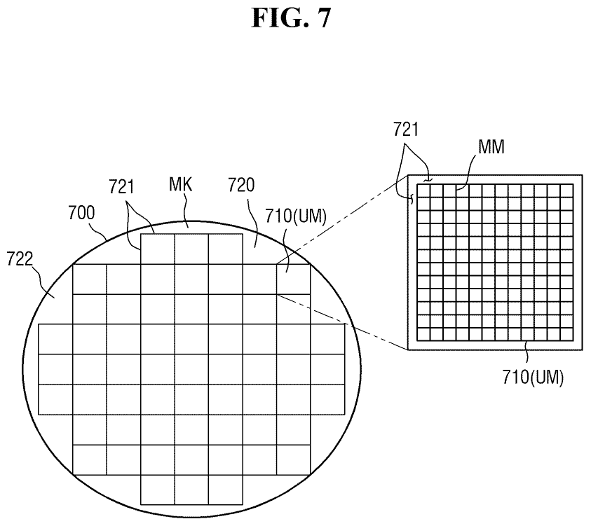

FIG. 6 is a schematic perspective view of a mask according to an embodiment. FIG. 7 is a schematic plan view of a mask according to an embodiment. In the schematic perspective view of FIG. 6, a unit mask UM is separated from a plurality of unit masks. The mask according to the embodiment shown in FIGS. 6 and 7 may be used in a process of depositing at least a part of the intermediate layer IL of the display panel 410 described above with reference to FIG. 5. For example, the intermediate layer IL may emit different colors from the sub-pixels SP1, SP2, and SP3.

Referring to FIGS. 6 and 7, a mask MK according to an embodiment may be a shadow mask in which a mask membrane MM is disposed on a silicon substrate 700. The mask MK according to the embodiment may be referred to as a silicon mask.

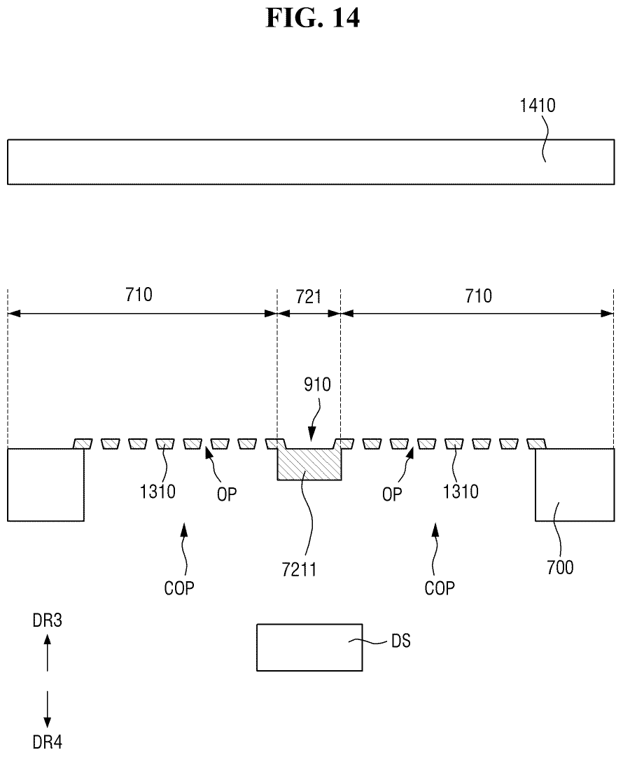

According to the embodiment, the mask MK may include a silicon substrate 700, and a mask rib 7211 (see FIG. 14) and a mask membrane MM may be disposed on the silicon substrate 700.

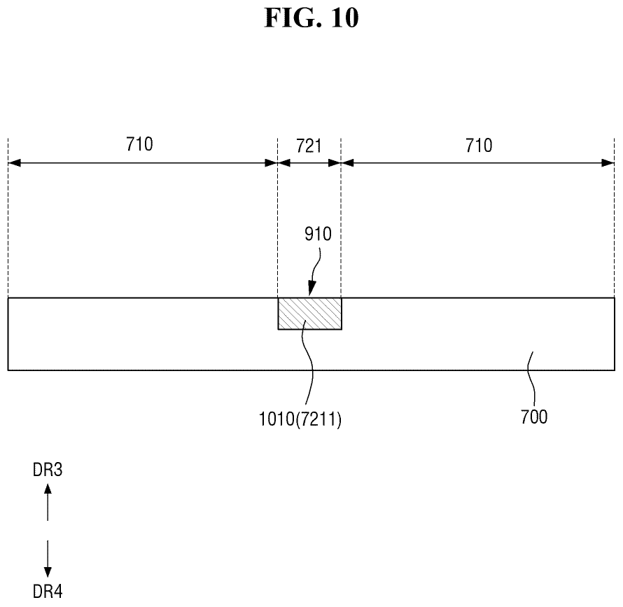

The mask rib 7211 are formed by a metal 1010 (see FIG. 10), as will be described later. Since the mask rib 7211 may include a metal material, it may be referred to as a metal mask rib 7211 or the like within the spirit and the scope of the disclosure. The mask rib 7211 may be interchangeably used with the term such as “mask grid.”

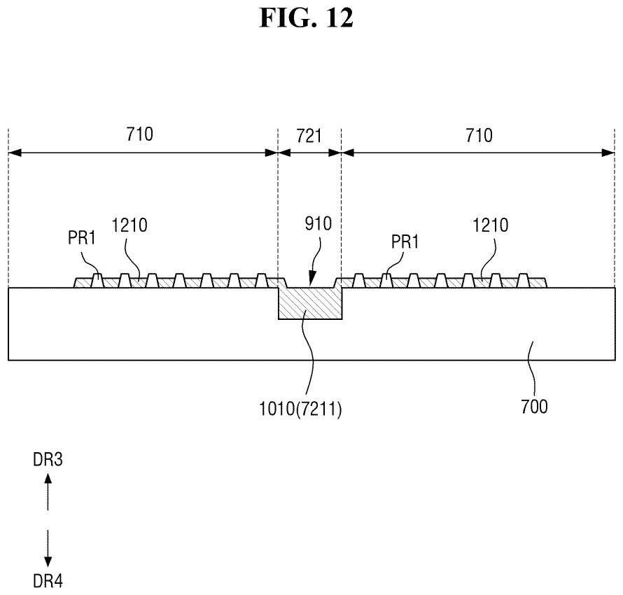

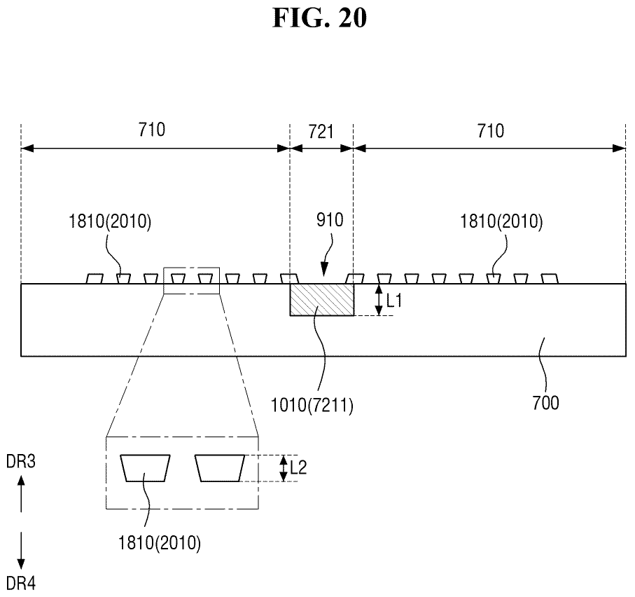

The mask membrane MM may be a part of the unit mask UM disposed in each of a plurality of cell areas 710. The mask membrane MM is formed by a plating film 1210 (sec FIG. 12) or a patterned inorganic film 1810 (see FIG. 20). If the mask membrane MM may include a metal material, it may be referred to as a metal mask membrane or the like within the spirit and the scope of the disclosure. In case that the mask membrane MM may include a metal, a metal 1210 (see FIG. 12) forming the mask membrane MM and the metal 1010 forming the mask rib 7211 may be made of the same material. For example, the mask rib 7211 and the mask membrane MM may include a plating film containing tungsten (W) or copper (Cu).

The silicon substrate 700 may include a plurality of cell areas 710, and a mask frame area 720 other than the plurality of cell areas 710. The mask frame area 720 may include a mask rib region 721 where the metal mask rib 7211 is disposed, and an outer frame region 722 disposed at the outermost position of the silicon substrate 700. A mask frame MF is disposed in the mask frame area 720. The mask frame MF may include a mask rib 7211 surrounding the cell areas 710. The silicon substrate 700 may be disposed in the outer frame region 722 as a part of the mask frame MF.

The mask rib region 721 may partition a plurality of cell areas 710. For example, the plurality of cell areas 710 may be arranged or disposed in a matrix, and the mask rib region 721 may surround the cell areas 710. The metal mask rib 7211 made of a metal material is disposed in the mask rib region 721. According to an embodiment, the mask rib 7211 is formed of a magnetic metal material, and thus it is possible to prevent the mask MK from sagging by using a magnetic member 1410 (see FIG. 14) (for example, a magnetic chuck) inside a vapor deposition machine (not shown). For example, the mask MK according to the embodiment is designed so that the thickness of the metal mask rib 7211 is larger than the thickness of the mask membrane MM, thereby increasing the magnetic force with the magnetic member 1410 and preventing sagging of the mask MK.

A cell opening COP and a unit mask UM that masks the cell opening COP at least partially may be located in each of the plurality of cell areas 710 of the silicon substrate 700.

The plurality of cell openings COP may penetrate the mask frame MF along the thickness direction of the mask MK (for example, third direction DR3). The plurality of cell openings COP may be created by partially etching the silicon substrate 700 from the rear side.

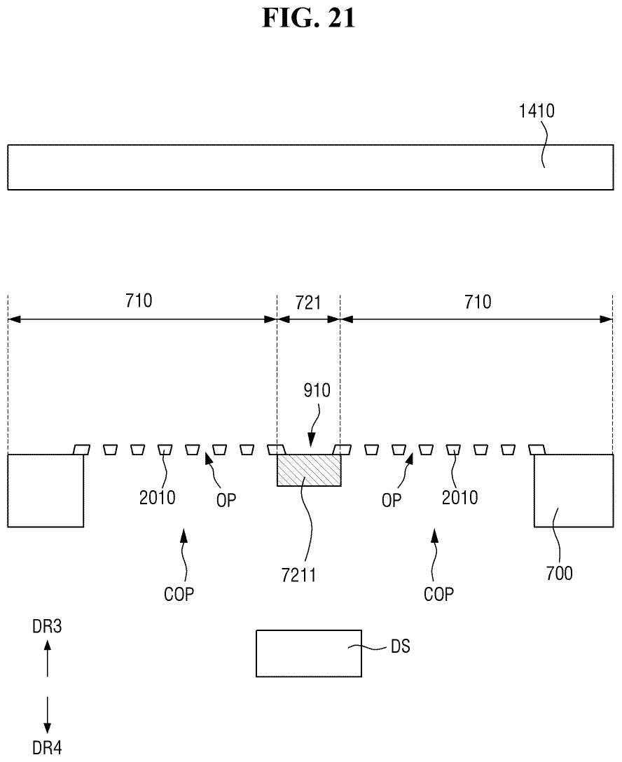

Each unit mask UM may include a mask membrane MM. The mask membrane MM may include mask shadows 1310 (see FIG. 14) or 2010 (see FIG. 21) that mask the cell opening COP at least partially, and mask openings OP located between adjacent mask shadows 1310 or 2010. The mask shadows 1310 or 2010 may be arranged or disposed in a matrix in each unit mask UM, and the mask openings OP may be located between the mask shadows 1310 or 2010. For example, the mask shadows 1310 or 2010 may be arranged or disposed to surround the mask openings OP.

The mask shadows 1310 or 2010 can work as a blocking unit that masks a substrate subjected to deposition (for example, the display panel 410, or backplane substrate) in case that the deposition material evaporates from a deposition source DS (see FIG. 14) inside the deposition machine. Accordingly, the deposition material generated from the deposition source DS may be deposited on the surface of the substrate subjected to deposition (for example, the display panel 410 or backplane substrate) through the mask openings OP of the mask membrane MM.

The mask openings OP of the mask membrane MM may be referred to as holes or mask holes. The mask openings OP may penetrate the unit masks UM along the thickness direction of the mask MK (for example, third direction DR3).

One unit mask UM may be used in a process of depositing one display panel 410. As used herein, the term “unit mask UM” may be interchangeably used with terms such as “mask unit UM” and “unit mask UM.”

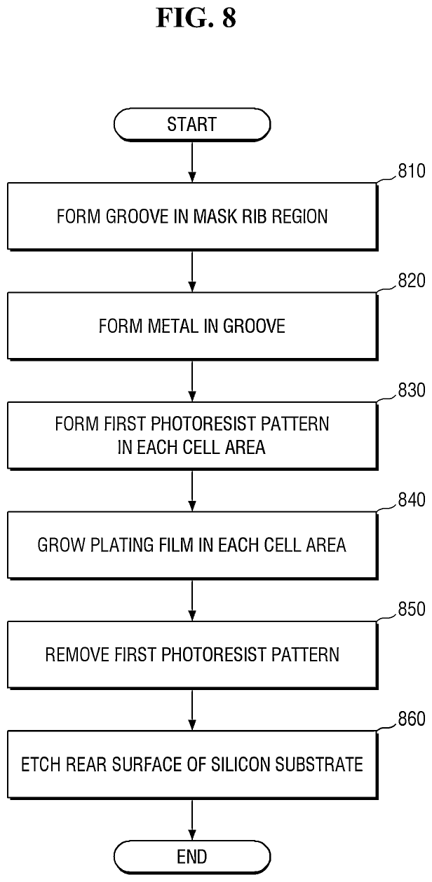

FIG. 8 is a flowchart for illustrating a method of fabricating a mask according to an embodiment.

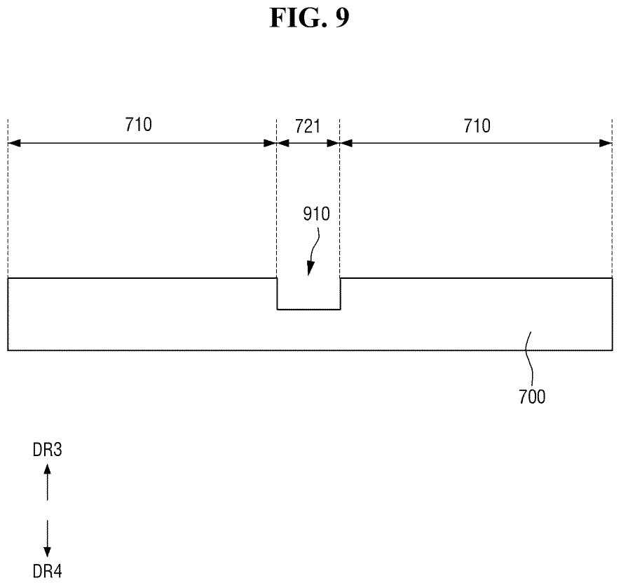

FIGS. 9 to 14 are schematic cross-sectional views for illustrating processing steps of the method of fabricating a mask according to an embodiment.

Hereinafter, with reference to FIGS. 8 to 14, a method of fabricating a mask according to an embodiment in which a mask membrane MM and a mask rib 7211 are formed of a metal will be described. It should be noted that some of the fabrication processes of the mask will be described. Other processes for forming the elements described herein may be additionally performed before or after the fabrication processes described below. Fabrication processes of masks may be additionally performed before or after the fabrication processes described below.

Referring to FIGS. 8 and 9, in step 810, a groove 910 may be formed in a mask rib region 721 of a silicon substrate 700. The silicon substrate 700 may be defined so that it is divided into a plurality of cell areas 710 and a mask frame area 720 excluding the plurality of cell areas 710. The mask frame area 720 may include the mask rib region 721 surrounding the borders of the plurality of cell areas 710. In Step 810, a groove 910 is formed in the defined mask rib region 721. The groove 910 provides a space where a metal mask rib 7211 (see FIG. 10) is formed in a subsequent process.

Referring to FIGS. 8 and 10, in step 820, a metal 1010 may be formed in the groove 910 to form a metal mask rib 7211. For example, the metal mask rib 7211 may be formed by growing a plating film in the groove 910. The plating film forming the metal mask rib 7211 may contain tungsten (W) or copper (Cu). The metal mask rib 7211 may be formed in the groove 910 and may surround the borders of the cell areas 710 accordingly.

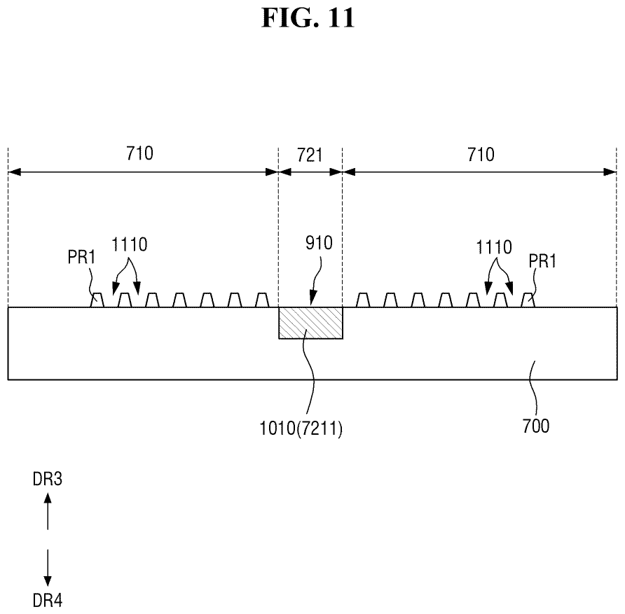

Referring to FIGS. 8 and 11, in step 830, a first photoresist pattern PR1 may be formed in each of the cell areas 710 of the silicon substrate 700. The first photoresist pattern PR1 may be formed by applying a photoresist composition on the silicon substrate 700 and patterning the photoresist composition. This first photoresist pattern PR1 may be disposed in each of the cell areas 710 and may include a plurality of first openings 1110. The plurality of first openings 1110 of the first photoresist pattern PR1 may expose the front surface of the silicon substrate 700 during the processes.

Although not shown in the drawings, a seed metal layer may be disposed on the silicon substrate 700, and the first photoresist pattern PR1 may be disposed on the seed metal layer.

The seed metal layer may work as a barrier metal that prevents the plating film 1210 (see FIG. 12) from permeation into the silicon substrate 700 in case that electroplating is performed, and may work as a seed. The seed metal layer may be a single film selected from conductive metals such as titanium (Ti), titanium nitride (TiN), tantalum (Ta), tantalum nitride (TaN), nickel (Ni), gold (Au), and molybdenum (Mo) or may be multiple films thereof.

Referring to FIGS. 8 and 12, in step 840, a plating film 1210 may be grown in each of the cell areas 710. The plating film 1210 may be grown in the first openings 1110 of the first photoresist pattern PR1. The plating film 1210 may be partially connected to the metal mask rib 7211 surrounding the borders of the cell areas 710. Embodiments are not limited to the plating film 1210 being connected to the metal mask rib 7211 at the borders of the cell areas 710. For example, at the borders of the cell areas 710, the plating film 1210 and the metal mask rib 7211 may not be connected with each other but may be disconnected from each other.

The cross section of the first photoresist pattern PR1 disposed around the plurality of first openings 1110 may have a taper shape. For example, the first photoresist pattern PR1 may have a taper shape by patterning a positive photoresist composition. The cross-section of the first photoresist pattern PR1 has a taper shape so that the cross section of a portion of the mask membrane MM (for example, the plating film 1210 which will become the mask shadows 1310) has a reverse taper shape.

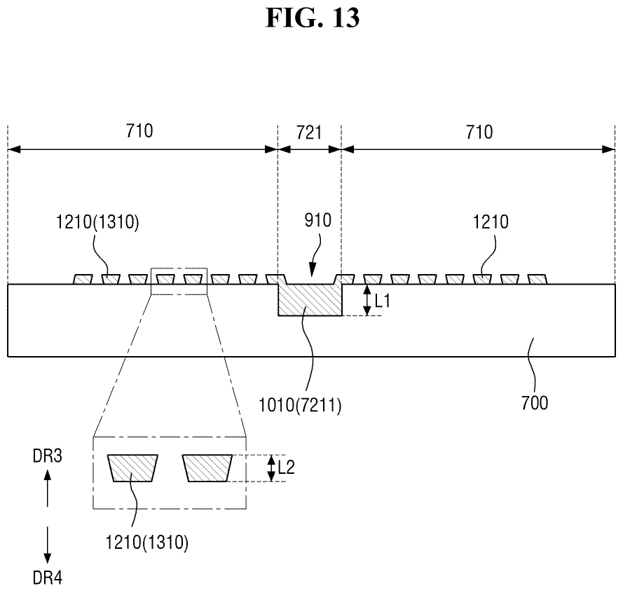

Referring to FIGS. 8 and 13, in step 850, the first photoresist pattern PR1 may be removed. The plating film 1210 remaining after the first photoresist pattern PR1 has been removed may work as the mask member MM in each of the cell areas 710. The mask shadows 1310 of the mask membrane MM may be formed by the plating film 1210, and the cross section may have a reverse taper shape. The mask membrane MM may include mask shadows 1310 formed by the plating film 1210 and mask openings OP located between adjacent mask shadows 1310.

The cross-section of the mask membrane MM may have a reverse taper shape in which the width becomes narrower from the front side DR3 of the silicon substrate 700 to the rear side DR4 of the silicon substrate 700. The cross-section of the mask openings OP may have a taper shape in which the width becomes wider from the front side DR3 of the silicon substrate 700 to the rear side DR4 of the silicon substrate 700. According to an embodiment, since the cross section of the mask membrane MM have the reverse taper shape, it is possible to reduce shadow defects during the deposition process.

According to an embodiment, the mask rib 7211 is formed of a magnetic metal material, and thus it is possible to prevent the mask MK from sagging by using a magnetic member 1410 (see FIG. 14) (for example, a magnetic chuck) inside a vapor deposition machine (not shown). For example, in the mask MK according to the embodiment, the thickness of the metal mask rib 7211 is designed to be larger than the thickness of the mask membrane MM, thereby increasing the magnetic force with the magnetic member 1410 and preventing sagging of the mask MK.

According to an embodiment, the thickness L1 of the metal mask rib 7211 may be different from the thickness L2 of the mask membrane MM. By way of example, the thickness L1 of the metal mask rib 7211 is greater than the thickness L2 of the mask membrane MM. According to this embodiment, the metal mask rib 7211 can have sufficient magnetic force so that it is possible to prevent the mask membrane MM from sagging. For example, in the mask MK according to the embodiment, even though the mask membrane MM sags due to its own weight, the metal mask ribs 7211 surrounding it exert a tensile force on the mask membrane MM with relatively strong magnetic force. In this manner, it is possible to reduce the sagging of the mask MK.

Referring to FIGS. 8 and 14, in step 860, the silicon substrate 700 may be etched from the rear surface. For example, a second photoresist pattern (not shown) may be formed on the rear surface of the silicon substrate 700. The second photoresist pattern may include a plurality of second openings (not shown) for defining cell openings COP associated with the plurality of unit masks UM, respectively. For example, each of the second openings may be associated with one cell opening COP. Subsequently, the silicon substrate 700 may be etched from its rear side DR4 using the second photoresist pattern. The rear side DR4 refers to the side on which the deposition source DS is located. The rear surface of the mask membrane MM formed with the plating film 1210 may be exposed by etching the silicon substrate 700. Although not shown in the drawings, the seed metal layer deposited on the front surface of the silicon substrate 700 before growing the plating film 1210 may work as an etch stopper in case that the silicon substrate 700 is etched from the rear surface.

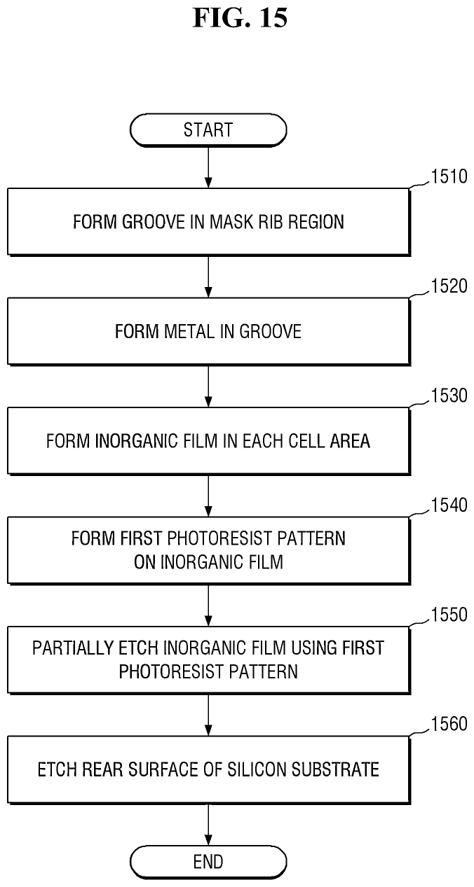

FIG. 15 is a flowchart for illustrating a method of fabricating a mask according to an embodiment.

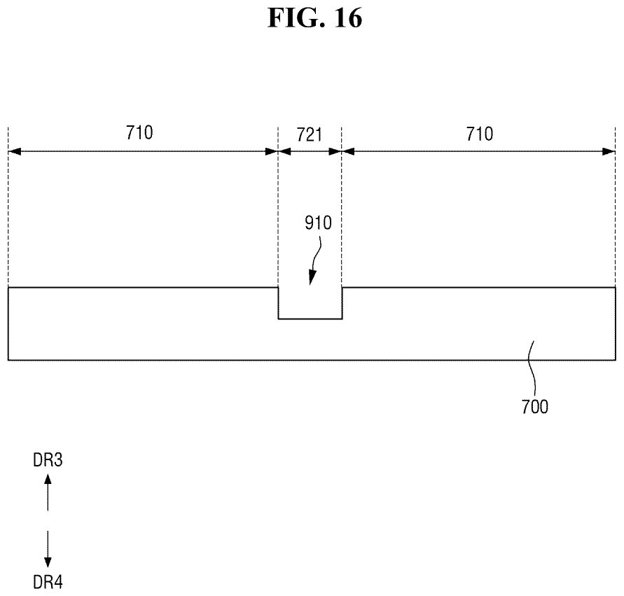

FIGS. 16 to 21 are schematic cross-sectional views of processing steps for illustrating a method of fabricating the mask shown in FIG. 15.

Hereinafter, with reference to FIGS. 15 to 21, a method of fabricating a mask according to an embodiment will be described, in which a mask rib 7211 is formed of a metal and a mask membrane MM is formed of an inorganic film 1810. It should be noted that some of the fabrication processes of the mask will be described. Other processes for forming the elements described herein may be additionally performed before or after the fabrication processes described below. Fabrication processes of masks may be additionally performed before or after the fabrication processes described below.

Referring to FIGS. 15 and 16, in step 1510, a groove 910 may be formed in a mask rib region 721 of a silicon substrate 700. The silicon substrate 700 may be defined to be divided into a plurality of cell areas 710 and a mask frame area 720 excluding the plurality of cell areas 710. The mask frame area 720 may include the mask rib region 721 surrounding the borders of the plurality of cell areas 710. In Step 810, a groove 910 is formed in the defined mask rib region 721. The groove 910 provides a space where a metal mask rib 7211 (see FIG. 10) is formed in a subsequent process.

Step 1510 may be substantially identical or similar to step 810 described above with reference to FIG. 8.

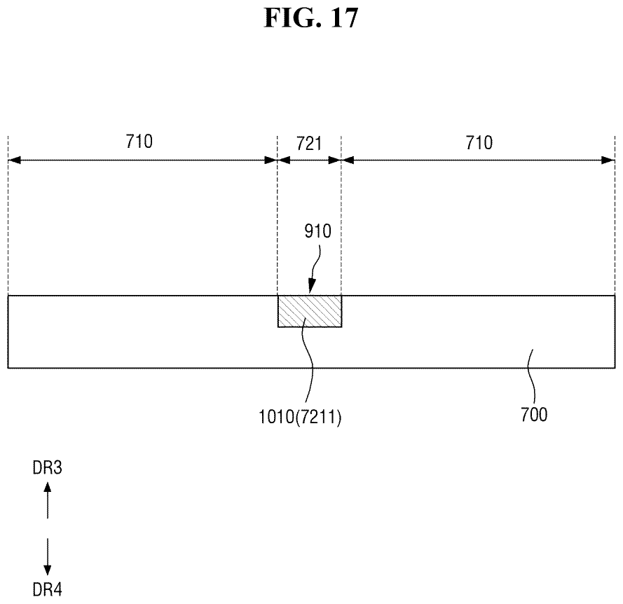

Referring to FIGS. 15 and 17, in step 1520, a metal 1010 may be formed in the groove 910 to form a metal mask rib 7211. For example, the metal mask rib 7211 may be formed by growing a plating film in the groove 910. The plating film forming the metal mask rib 7211 may contain tungsten (W) or copper (Cu). The metal mask rib 7211 may be formed in the groove 910 and may surround the borders of the cell areas 710 accordingly.

Step 1510 may be substantially identical or similar to step 820 described above with reference to FIG. 8.

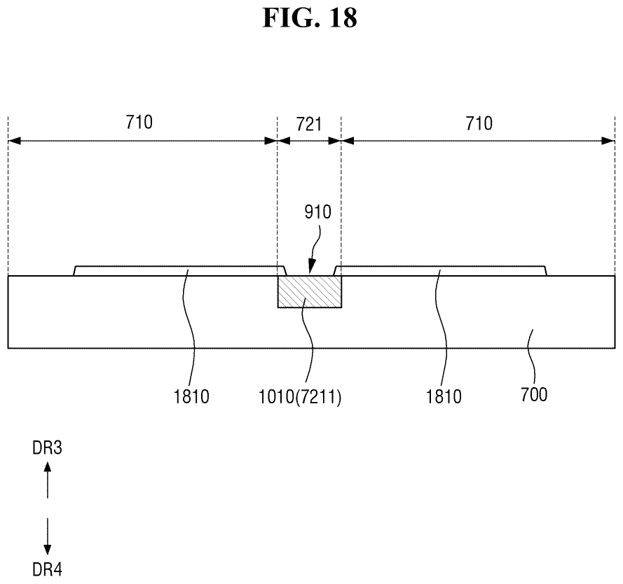

Referring to FIGS. 15 and 18, in step 1530, an inorganic film 1810 may be formed in each cell area. An inorganic film 1810 may be deposited on each cell area 710. The inorganic film 1810 may include a silicone-based material. For example, a pattern of the inorganic film 1810 may include at least one of: silicon (Si), silicon nitride (SiNₓ), silicon oxynitride (SiON), silicon oxide (SiOₓ), titanium oxide (TiOₓ), amorphous silicon (a-Si) and aluminum oxide layer (AlOₓ).

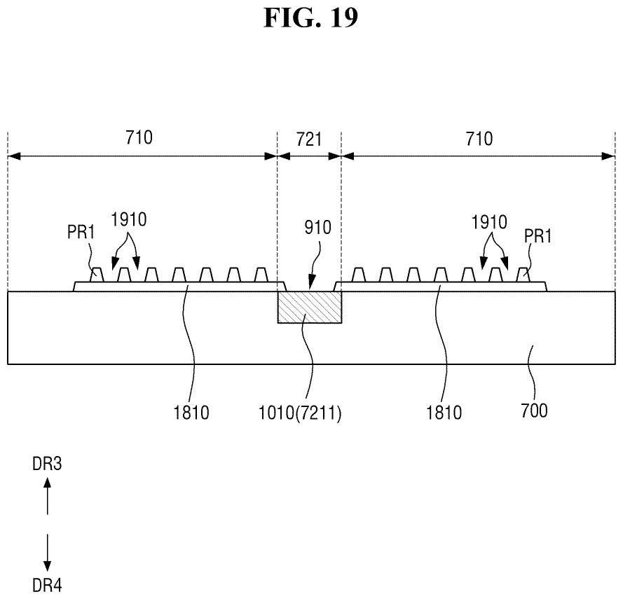

Referring to FIGS. 15 and 19, in step 1540, a first photoresist pattern may be formed on the inorganic film 1810. The first photoresist pattern PR1 may be formed by applying a photoresist composition on the inorganic film 1810 and patterning the photoresist composition. This first photoresist pattern PR1 may be disposed on the inorganic film 1810 in each of the cell areas 710 and may include a plurality of first openings 1110. The plurality of first openings 1110 of the first photoresist pattern PR1 may expose the front surface of the inorganic film 1810 during the processes.

The cross section of the first photoresist pattern PR1 may have a taper shape. For example, the first photoresist pattern PR1 may have a taper shape by patterning a positive photoresist composition. The cross-section of the first photoresist pattern PR1 has a taper shape so that the cross section of the mask membrane MM has a reverse taper shape.

Referring to FIGS. 15 and 20, in step 1550, the inorganic film 1810 may be partially etched using the first photoresist pattern PR1. In step 1550, the inorganic film 1810 may be etched in the first openings 1110 of the first photoresist pattern PR1. After etching the inorganic film 1810, the first photoresist pattern PR is removed. A portion of the inorganic film 1810 remaining after the first photoresist pattern PR has been removed may be referred to as the “pattern of the inorganic layer 1810.” The pattern of the inorganic film 1810 remaining after the etching process using the first photoresist pattern PR1 may become a mask membrane MM. The mask shadows 2010 (see FIG. 20) of the mask membrane MM may be formed by the inorganic film 1810, and the cross section may have a reverse taper shape. The mask membrane MM may include mask shadows 2010 formed by the inorganic film 1810 and mask openings OP (see FIG. 21) located between adjacent mask shadows 2010.

According to an embodiment, the thickness L1 of the metal mask rib 7211 may be different from the thickness L2 of the mask membrane MM. By way of example, the thickness L1 of the metal mask rib 7211 is greater than the thickness L2 of the mask membrane MM. According to this embodiment, the metal mask rib 7211 can have sufficient magnetic force so that it is possible to prevent the mask membrane MM from sagging. For example, in the mask MK according to the embodiment, even though the mask membrane MM sags due to its own weight, the metal mask ribs 7211 surrounding it exert a tensile force on the mask membrane MM with relatively strong magnetic force. In this manner, it is possible to reduce the sagging of the mask MK.

Referring to FIGS. 15 and 21, in step 1560, the rear surface of the silicon substrate 700 may be etched. For example, a second photoresist pattern (not shown) may be formed on the rear surface of the silicon substrate 700. The second photoresist pattern may include a plurality of second openings (not shown) for defining cell openings COP associated with the plurality of unit masks UM, respectively. For example, each of the second openings may be associated with one cell opening COP. Subsequently, the silicon substrate 700 may be etched from its rear side DR4 using the second photoresist pattern. The rear side DR4 refers to the side on which the deposition source DS is located. The rear surface of the mask membrane MM formed with the inorganic film 1810 may be exposed by etching the silicon substrate 700.

According to the method of fabricating a deposition mask according to the embodiments, the alignment accuracy of the mask can be improved by preventing sagging of the mask by applying a mask grid (or mask rib 7211) to which a magnetic metal is applied, and it is possible to prevent mura defects caused by sagging of the mask.

In concluding the detailed description, those skilled in the art will appreciate that many variations and modifications can be made to the disclosed embodiments without substantially departing from the principles of the disclosure. Therefore, the disclosed embodiments are used in a generic and descriptive sense only and not for purposes of limitation.

What is claimed is:

1. A method of fabricating a mask, the method comprising:
defining a plurality of cell areas and a mask frame area disposed on a silicon substrate, the mask frame area excluding the plurality of cell areas, wherein the mask frame area comprises a mask rib region partitioning the plurality of cell areas and an outer frame region disposed at an outermost position of the silicon substrate;
forming a groove in the mask rib region;
forming a metal mask rib by forming a metal in the groove;
forming a photoresist pattern comprising a plurality of openings in each of the plurality of cell areas;
growing a plating film in each of the plurality of cell areas;
forming a mask membrane formed of the plating film by removing the photoresist pattern; and
etching a rear surface of the silicon substrate to form cell openings associated with the plurality of cell areas, respectively.

2. The method of claim 1, wherein a cross-section of the mask membrane has a substantially reverse taper shape in which a width becomes narrower from a front side of the silicon substrate toward a rear side of the silicon substrate.

3. The method of claim 1, wherein a thickness of the metal mask rib is greater than a thickness of the mask membrane.

4. The method of claim 1, wherein the mask membrane comprises mask shadows formed by the plating film and mask openings disposed between adjacent mask shadows.

5. The method of claim 4, wherein a cross-section of the mask openings has a substantially taper shape in which a width becomes wider from a front side of the silicon substrate toward a rear side of the silicon substrate.

6. The method of claim 1, wherein the plating film contains tungsten (W).

7. The method of claim 1, wherein the plating film contains copper (Cu).

8. A method of fabricating a mask, the method comprising:
defining a plurality of cell areas and a mask frame area on a silicon substrate, the mask frame area excluding the plurality of cell areas, wherein the mask frame area comprises a mask rib region partitioning the plurality of cell areas and an outer frame region disposed at an outermost position of the silicon substrate;
forming a groove in the mask rib region;
forming a metal mask rib by forming a metal in the groove;
forming an inorganic film in each of the plurality of cell areas;
forming a photoresist pattern comprising a plurality of openings on the inorganic film;
forming a mask membrane by etching a portion of the inorganic film using the photoresist pattern;
removing the photoresist pattern; and
etching a rear surface of the silicon substrate to form cell openings associated with the plurality of cell areas, respectively.

9. The method of claim 8, wherein a cross-section of the mask membrane has a substantially reverse taper shape in which a width becomes narrower from a front side of the silicon substrate toward a rear side of the silicon substrate.

10. The method of claim 8, wherein a thickness of the metal mask rib is greater than a thickness of the mask membrane.

11. The method of claim 8, wherein the mask membrane comprises mask shadows formed by a plating film and mask openings disposed between adjacent mask shadows.

12. The method of claim 11, wherein a cross-section of the mask openings has a substantially taper shape in which a width becomes wider from a front side of the silicon substrate toward a rear side of the silicon substrate.

13. A mask comprising:
a silicon substrate comprising a plurality of cell areas and a mask frame area excluding the plurality of cell areas, wherein the mask frame area comprises a mask rib region partitioning the plurality of cell areas and an outer frame region disposed at an outermost position of the silicon substrate;
a metal mask rib disposed in the mask rib region; and
a mask membrane disposed in each of the plurality of cell areas.

14. The mask of claim 13, wherein the mask membrane is formed by a plating film disposed on the silicon substrate.

15. The mask of claim 14, wherein the plating film contains tungsten (W).

16. The mask of claim 14, wherein the plating film contains copper (Cu).

17. The mask of claim 13, wherein the mask membrane is formed by an inorganic film disposed on the silicon substrate.

18. The mask of claim 13, wherein a cross-section of the mask membrane has a substantially reverse taper shape in which a width becomes narrower from a front side of the silicon substrate toward a rear side of the silicon substrate.

19. The mask of claim 13, wherein a thickness of the metal mask rib is greater than a thickness of the mask membrane.

20. The mask of claim 13, wherein each of the plurality of cell areas comprises a cell opening exposing the mask membrane as a rear surface of the silicon substrate is etched.
